(19) United States
(12) Patent Application Publication
(10) Pub. No.: US 2015/0056811 A1
(43) Pub. Date: Feb. 26, 2015

(54) STACKED STRUCTURE BODY AND PATTERN FORMATION METHOD

(71) Applicant: Kabushiki Kaisha Toshiba, Minato-ku (JP)

(72) Inventors: Takehiro KONDOH, Mie-ken (JP); Yasuhiko Sato, Mie-ken (JP)

(73) Assignee: Kabushiki Kaisha Toshiba, Minato-ku (JP)

(21) Appl. No.: 14/175,125

(22) Filed: Feb. 7, 2014

(30) Foreign Application Priority Data
Aug. 22, 2013 (JP) 2013-172063

(51) Int. Cl. H01L 21/3213; H01L 21/027

(52) U.S. Cl. CPC H01L 21/32133; H01L 21/32139; H01L 21/0271
USPC 438/703; 428/172

(57) ABSTRACT

According to one embodiment, a stacked structure body includes: an underlayer; a mask layer provided on the underlayer; a copolymer-containing layer provided on the mask layer, the copolymer-containing layer containing a metal and carbon, and the copolymer-containing layer including a first copolymer region and a second copolymer region provided on the first copolymer region, and the second copolymer region having a lower proportion of a metal concentration to a carbon concentration than the first copolymer region; and a resist pattern provided on the copolymer-containing layer.

### CROSS-REFERENCE TO RELATED APPLICATIONS

This application is based upon and claims the benefit of priority from Japanese Patent Application No.2013-172063, filed on Aug. 22, 2013; the entire contents of which are incorporated herein by reference.

### FIELD

Embodiments described herein relate generally to a stacked structure body and a pattern formation method.

### BACKGROUND

A memory cell of a three-dimensional structure is receiving attention in order to achieve high integration of semiconductor memories. When the memory cell of a three-dimensional structure is formed, there is a case where a resist layer is used as a mask layer to dry-etch a thick stacked structure. However, when the thick stacked structure is dry-etched, a thick resist layer is needed and this causes the problems of resist pattern collapse and insufficient resolving power.

In this regard, a technology in which a thick stacked structure can be dry-etched using a thin resist layer is drawing attention. This is a method in which a metal-containing resin as an intermediate film is formed under the resist layer. However, the optical constant k (the extinction coefficient) of the metal-containing resin to exposure light is relatively high. Thus, the light reflection at the interface between the resist layer and the intermediate film is large, and a resist pattern with a good configuration may not be formed.

The interface reflection is suppressed by further forming a reflection prevention layer called an organic BARC (bottom anti-reflection coating) layer between the intermediate film and the resist layer. However, cost reduction is difficult because the organic BARC layer is expensive and the number of manufacturing processes is increased.

### BRIEF DESCRIPTION OF THE DRAWINGS

FIG. 1A is a schematic cross-sectional view showing a stacked structure body according to an embodiment, and FIG. 1B is a schematic plan view showing the stacked structure body according to the embodiment;

FIG. 2A is a diagram showing an example of the molecular structure of the second copolymer region according to the embodiment, and FIG. 2B is a diagram showing an example of the molecular structure of the first copolymer region according to the embodiment;

FIG. 3A to FIG. 3D are schematic cross-sectional views showing a pattern formation method according to the embodiment; and

FIG. 4 is a schematic cross-sectional view showing a pattern formation method according to a reference example.

### DETAILED DESCRIPTION

In general, according to one embodiment, a stacked structure body includes: an underlayer; a mask layer provided on the underlayer; a copolymer-containing layer provided on the mask layer, the copolymer-containing layer containing a metal and carbon, and the copolymer-containing layer including a first copolymer region and a second copolymer region provided on the first copolymer region, and the second copolymer region having a lower proportion of a metal concentration to a carbon concentration than the first copolymer region; and a resist pattern provided on the copolymer-containing layer.

Hereinbelow, embodiments are described with reference to the drawings. In the following description, identical components are marked with the same reference numerals, and a description of components once described is omitted as appropriate.

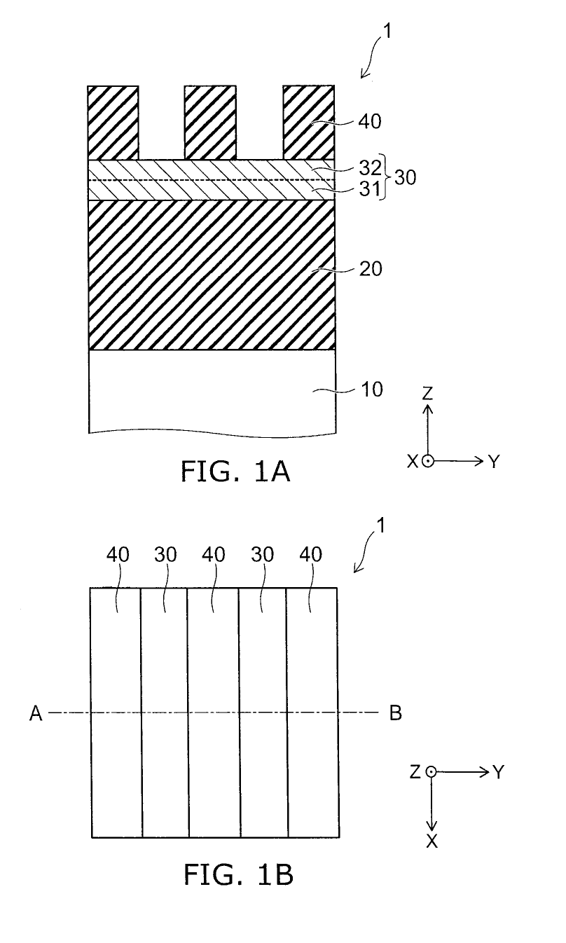

FIG. 1A is a schematic cross-sectional view showing a stacked structure body according to an embodiment, and FIG. 1B is a schematic plan view showing the stacked structure body according to the embodiment.

A stacked structure body 1 according to the embodiment includes an underlayer 10, a mask layer 20, a copolymer-containing layer 30, and a resist pattern 40.

The mask layer 20 is provided on the underlayer 10. The copolymer-containing layer 30 is provided on the mask layer 20. The copolymer-containing layer 30 is a copolymer-containing layer containing a metal, oxygen, and carbon. The copolymer-containing layer 30 has a first copolymer region 31 and a second copolymer region 32. The second copolymer region 32 is provided on the first copolymer region 31. The proportion of the metal concentration to the carbon concentration in the second copolymer region 32 is smaller than the proportion of the metal concentration to the carbon concentration in the first copolymer region 31. The resist pattern 40 is provided on the copolymer-containing layer 30.

Although FIG. 1B illustrates a resist pattern 40 in a stripe configuration, the resist pattern 40 may be in an island configuration.

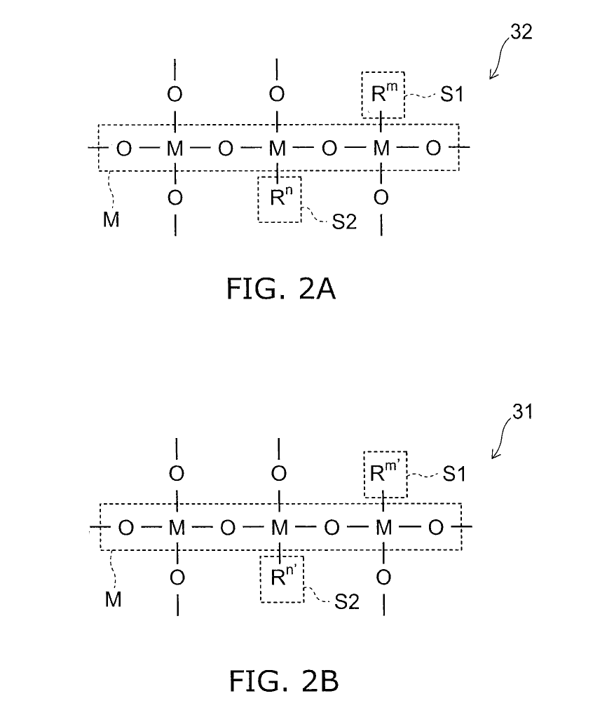

FIG. 2A is a diagram showing an example of the molecular structure of the second copolymer region according to the embodiment, and FIG. 2B is a diagram showing an example of the molecular structure of the first copolymer region according to the embodiment.

The main chain M of each of the first copolymer region 31 and the second copolymer region 32 contains a metal and oxygen (O). Here, as the metal, one of titanium (Ti), chromium (Cr), molybdenum (Mo), tungsten (W), zinc (Zn), aluminum (Al), gallium (Ga), indium (In), and tantalum (Ta) is given.

Each of the first copolymer region 31 and the second copolymer region 32 contains carbon (C). Side chains S1 and S2 of them contain one of an alkyl group, a cycloalkyl group, an alkoxy group, and an alkoxycarbonyl group. A substituent Rₙ and a substituent Rₘ may be different substituents or the same substituent. Similarly, a substituent R_{n′} and a substituent R_{m′} may be different or the same. Each of the substituent Rₙ and the substituent Rₘ may exist in plural in the second copolymer region 32. Similarly, each of the substituent R_{n′} and the substituent R_{m′} may exist in plural in the first copolymer region 31. As the alkyl group (CₙHₙ₊₁), an alkyl group with the number n of carbon atoms of 1 to 10, a cycloalkyl group with the number n of carbon atoms of 3 to 10, or the like is given. As the alkoxy group (OCₙHₙ₊₁), for example, a methoxy group, an ethoxy group, a 1-protoxy group, a 2-protoxy group, a n-butoxy group, and the like are given. As the alkoxycarbonyl group, for example, a group synthesized from one of acetic acid, trifluoroacetic acid, 2-methylpropanoic acid, pentanoic acid, and butanoic acid and an alcohol, and the like are given.

In the embodiment, the proportion of the metal concentration (atoms·%) to the carbon concentration (atoms·%) in the second copolymer region 32 is smaller than the proportion of the metal concentration to the carbon concentration in the first copolymer region 31. In other words, the second copolymer region 32 is more hydrophobic than the first copolymer region 31.

In the second copolymer region 32, the side chain S1 is an alkyl group having 9 or more carbon atoms, as an example. The side chain S2 is an alkoxy group having 6 or more carbon atoms. In the first copolymer region 31, the side chain 51 is a methyl group. The side chain S2 is a methoxy group. In such a case, the proportion of the metal concentration (atoms·%) to the carbon concentration (atoms·%) in the second copolymer region 32 is smaller than the proportion of the metal concentration to the carbon concentration in the first copolymer region 31.

Since the second copolymer region 32 contains a higher percentage of carbon than the first copolymer region 31, the k value (the optical constant) to exposure light used in photolithography is smaller in the second copolymer region 32 than in the first copolymer region 31.

In the case where the film thickness of the second copolymer region 32 is 15 nm and the film thickness of the first copolymer region 31 is 35 nm, the optical constant k of the second copolymer region 32 is 0.2 and the optical constant k of the first copolymer region 31 is 0.4, for example. The light reflectance at the interface between the copolymer-containing layer 30 and the mask layer 20 under the copolymer-containing layer 30 is 0.89%, for example.

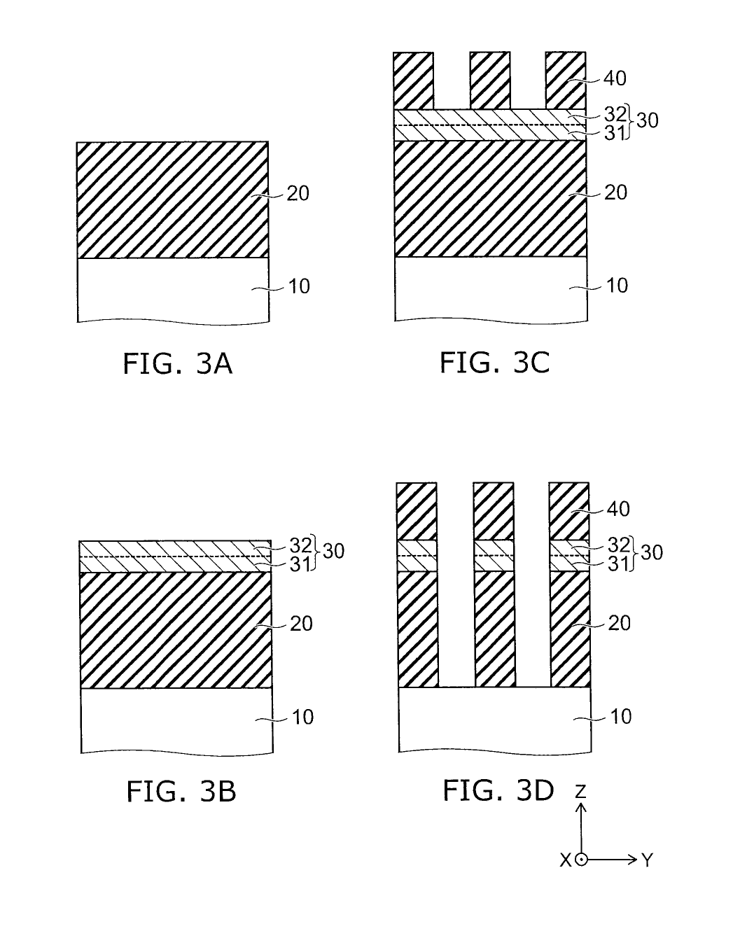

FIG. 3A to FIG. 3D are schematic cross-sectional views showing a pattern formation method according to the embodiment.

First, as shown in FIG. 3A, the mask layer 20 is formed on the underlayer 10. The underlayer 10 is a semiconductor layer of silicon or the like, an interlayer insulating film of silicon oxide, silicon nitride, or the like, or a conductive layer of impurity-doped polysilicon, tungsten, titanium, or the like, for example.

The mask layer 20 is a carbon film, for example. The mask layer 20 is formed by CVD (chemical vapor deposition). The film thickness of the mask layer 20 is 500 nm, for example.

Next, as shown in FIG. 3B, the copolymer-containing layer 30 is formed on the mask layer 20. As described above, the copolymer-containing layer 30 has the first copolymer region 31 and the second copolymer region 32.

In the formation of the copolymer-containing layer 30, first, a solution in which the copolymer contained in the first copolymer region 31 is dissolved in an organic solvent is formed on the mask layer 20 by the spin coating method. After that, heating treatment is performed on the solution at 220° C. for one minute, for example. Thereby, a first copolymer region 31 with a film thickness of 40 nm is formed.

A cross-linking promoter and/or a surface active agent may be added to the solution. For example, by adding a cross-linking promoter to the solution, the polymerization degree of the first copolymer region is increased. By mixing a surface active agent into the solution, the stress applied to the first copolymer region 31 during spin coating is relaxed.

Subsequently, the second copolymer region 32 is formed on the first copolymer region 31 by a similar method to the first copolymer region 31.

Next, as shown in FIG. 3C, the resist pattern 40 is formed on the copolymer-containing layer 30. The film thickness of the resist pattern 40 is 100 nm, for example. The resist pattern 40 is formed by photolithography and dry etching.

The resist is an ArF positive resist, for example. The resist is applied uniformly to the copolymer-containing layer 30 by the spin coating method, and then heating treatment is performed on the resist at 130° C. for one minute. After that, exposure is performed on the resist using an ArF excimer laser exposure apparatus and a halftone mask with a transmittance of 6% under the conditions of NA: 0.85 and ⅔ annular illumination. Subsequently, heating treatment is performed on the resist at 100° C. for one minute.

Subsequently, the development of the resist is performed using a 2.38 weight % tetramethylammonium hydroxide (TMAH) aqueous solution. Thereby, as shown in FIG. 3C, resist pattern features 40 with a rectangular cross-sectional shape are formed. The light reflectance at the interface between the resist pattern 40 and the copolymer-containing layer 30 is 0.88 to 0.89%. The reason why such a low light reflectance is obtained is that the second copolymer region 32 with a smaller k value is made to exist locally on the first copolymer region 31.

The line width in the Y-direction of the resist pattern feature 40 is 120 nm, for example. The space width between adjacent resist pattern features 40 is 120 nm, for example.

The exposure light for forming the resist pattern 40 may be the i line, KrF light, EUV light, or the like. The resist pattern 40 may be a cross-linkable negative resist or a negative resist using organic development.

After that, as shown in FIG. 3D, dry etching processing is performed on the copolymer-containing layer 30 exposed from the resist pattern and the underlying mask layer 20. Thereby, a mask layer 20 in which the pattern of the resist pattern 40 is transferred is formed on the underlayer 10. After that, dry etching processing is performed on the underlayer 10 exposed from the mask layer 20.

As the gas for dry-etching the underlayer 10, for example, oxygen (O₂), an oxygen-containing gas such as carbon oxide (CO and CO₂), an inert gas such as helium (He), nitrogen (N₂), and argon (Ar), chlorine (Cl₂), a chlorine-based gas such as boron chloride (BCl₃), and a fluorine-based gas (CHF₃, CF₄, etc.) are given. Also hydrogen (H₂) and ammonia (NH₃) may be used. These gases may be mixed.

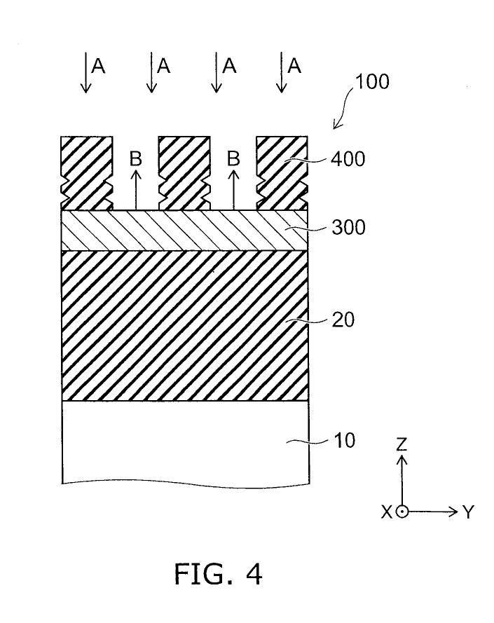

FIG. 4 is a schematic cross-sectional view showing a pattern formation method according to a reference example.

A stacked structure body 100 according to the reference example includes the underlayer 10, the mask layer 20, a metal-containing resin layer 300, and a resist pattern 400. Here, unlike the embodiment, the metal-containing resin layer 300 does not include the first copolymer region 31 and the second copolymer region 32. The optical constant k of the metal-containing resin layer 300 when the film thickness of the metal-containing resin layer 300 is 50 nm is 0.4, for example. The light reflectance at the interface between the metal-containing resin layer 300 and the resist pattern 400 is 2.2% or more.

If the resist pattern 400 is formed in such a state where the light reflectance at the interface is high, exposure light A and the reflected light B from the interface mentioned above are likely to interfere with each other. Consequently, the intensity of exposure light becomes higher or lower near the interface, as compared to near the upper portion of the resist pattern 400.

Therefore, in the reference example, the cross-sectional shape of the resist pattern feature 400 does not become a rectangle like that of the embodiment, and the side surface of the resist pattern feature 400 becomes irregular, for example.

Here, to reduce the light reflectance at the interface between the metal-containing resin layer 300 and the resist pattern 400, there is a method in which an organic BARC layer is provided between the metal-containing resin layer 300 and the resist pattern 400. However, in this method, costs are increased by the cost of the material of the organic BARC layer and the increase in the number of processes caused by the manufacturing of the organic BARC layer.

In contrast, in the embodiment, an organic BARC layer is not used, and the copolymer-containing layer 30 is used as a reflection prevention film. By using the copolymer-containing layer 30, the thickness of the resist pattern 40 can be reduced. Furthermore, the cross section of the resist pattern feature 40 becomes a rectangle as described above. Furthermore, cost reduction is achieved.

The term “on” in “a portion A is provided on a portion B” refers to the case where the portion A is provided on the portion B such that the portion A is in contact with the portion B and the case where the portion A is provided above the portion B such that the portion A is not in contact with the portion B. The term “on” in “a portion A is provided on a portion B” refers to the case where the portion A is provided under the portion B such that the portion A and the portion B are turned upside down and the portion A comes abreast of the portion B. This is because that, if the semiconductor device according to embodiments are rotated, the structure of the semiconductor device remains unchanged before and after rotation.

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A stacked structure body comprising:
an underlayer;
a mask layer provided on the underlayer;
a copolymer-containing layer provided on the mask layer, the copolymer-containing layer containing a metal and carbon, and the copolymer-containing layer including a first copolymer region and a second copolymer region provided on the first copolymer region, and the second copolymer region having a lower proportion of a metal concentration to a carbon concentration than the first copolymer region; and
a resist pattern provided on the copolymer-containing layer.

2. The stacked structure body according to claim 1, wherein the copolymer-containing layer further contains oxygen.

3. The stacked structure body according to claim 1, wherein
a main chain of each of the first copolymer region and the second copolymer region contains a metal and oxygen and
a side chain of each of the first copolymer region and the second copolymer region contains carbon.

4. The stacked structure body according to claim 3, wherein the side chain contains one of an alkyl group, an alkoxy group, and a carbonyl group.

5. The stacked structure body according to claim 1, wherein the metal contains one of titanium (Ti), chromium (Cr), molybdenum (Mo), tungsten (W), zinc (Zn), aluminum (Al), gallium (Ga), indium (In), and tantalum (Ta).

6. The stacked structure body according to claim 4, wherein the alkyl group (CₙHₙ₊₁) contains an alkyl group with the number n of carbon atoms of 1 to 10 or a cycloalkyl group with the number n of carbon atoms of 3 to 10.

7. The stacked structure body according to claim 4, wherein the alkoxy group contains one of a methoxy group, an ethoxy group, a 1-protoxy group, a 2-protoxy group, and a n-butoxy group.

8. The stacked structure body according to claim 4, wherein a carbonyl group contains a group synthesized from one of acetic acid, trifluoroacetic acid, 2-methylpropanoic acid, pentanoic acid, and butanoic acid and an alcohol.

9. A pattern formation method comprising:
forming a mask layer on an underlayer;
forming a copolymer-containing layer on the mask layer, the copolymer-containing layer containing a metal and carbon, and the copolymer-containing layer including a first copolymer region and a second copolymer region formed on the first copolymer region, and the second copolymer region having a lower proportion of a metal concentration to a carbon concentration than the first copolymer region;
forming a resist layer patterned on the copolymer-containing layer; and
etching the copolymer-containing layer exposed from the resist pattern and the mask layer under the copolymer-containing layer exposed from the resist pattern to form the mask layer on the underlayer, and a pattern of the resist layer is transferred in the mask.

10. The method according to claim 9, wherein the copolymer-containing layer further contains oxygen.

11. The method according to claim 9, wherein
a main chain of each of the first copolymer region and the second copolymer region contains a metal and oxygen and
a side chain of each of the first copolymer region and the second copolymer region contains carbon.

12. The method according to claim 11, wherein the side chain contains one of an alkyl group, an alkoxy group, and a carbonyl group.

13. The method according to claim 9, wherein the metal contains one of titanium (Ti), chromium (Cr), molybdenum (Mo), tungsten (W), zinc (Zn), aluminum (Al), gallium (Ga), indium (In), and tantalum (Ta).

14. The method according to claim 12, wherein the alkyl group (CₙHₙ₊₁) contains an alkyl group with the number n of carbon atoms of 1 to 10 or a cycloalkyl group with the number n of carbon atoms of 3 to 10.

15. The method according to claim 12, wherein the alkoxy group contains one of a methoxy group, an ethoxy group, a 1-protoxy group, a 2-protoxy group, and a n-butoxy group.

16. The method according to claim 12, wherein a carbonyl group contains a group synthesized from one of acetic acid, trifluoroacetic acid, 2-methylpropanoic acid, pentanoic acid, and butanoic acid and an alcohol.
